(19) United States
(12) Patent Application Publication
(10) Pub. No.: US 2017/0249980 A1
(43) Pub. Date: Aug. 31, 2017

(54) SEMICONDUCTOR APPARATUS INCLUDING COLUMN SELECTION SIGNAL GENERATION CIRCUIT

(71) Applicant: SK hynix Inc., Icheon-si Gyeonggi-do (KR)

(72) Inventors: Soo Young JANG, Icheon-si Gyeonggi-do (KR); Jae Hoon CHA, Icheon-si Gyeonggi-do (KR)

(21) Appl. No.: 15/193,750

(22) Filed: Jun. 27, 2016

(30) Foreign Application Priority Data
Feb. 29, 2016 (KR) 10-2016-0024344

(51) Int. Cl. G11C 8/10; G11C 8/08; G11C 7/12

(52) U.S. Cl. CPC G11C 8/10; G11C 7/12; G11C 8/08

(57) ABSTRACT

A semiconductor apparatus may include a column select signal generation circuit and a control signal generation circuit. The column select signal generation circuit may generate a column select signal by driving an output node of the column select signal with a first drivability in response to a column decoding signal and adjust the first drivability according to a drivability control signal. The control signal generation circuit may generate the drivability control signal according to a row decoding signal.

### CROSS-REFERENCES TO RELATED APPLICATION

The present application claims priority under 35 U.S.C. §119(a) to Korean application number 10-2016-0024344 filed on Feb. 29, 2016, in the Korean Intellectual Property Office, which is incorporated herein by reference in its entirety.

### BACKGROUND

1. Technical Field

Various embodiments generally relate to a semiconductor integrated circuit, and more particularly to a column select signal generation circuit and a semiconductor apparatus using the same.

2. Related Art

Typically semiconductor memory devices are designed with the memory cells laid out in a cell array, and a large number of memory cells may be laid out in the cell array. Given the array architecture, a data access time may vary depending on where the memory cell to be accessed resides.

Due to the different physical distances between where the memory cell to be accessed resides and where a read/write is requested, a data skew may occur, and an operation timing margin might be limited.

### SUMMARY

In an embodiment of the present disclosure, a semiconductor apparatus may include a column select signal generation circuit and a control signal generation circuit. The column select signal generation circuit may generate a column select signal by driving an output node of the column select signal with a first drivability in response to a column decoding signal and adjust the first drivability according to a drivability control signal. The control signal generation circuit may generate the drivability control signal according to a row decoding signal.

In an embodiment of the present disclosure, a semiconductor apparatus may include a memory region and a column select signal generation circuit. The memory region may include a plurality of memory blocks having a column path which is enabled according to a column select signal. The column select signal generation circuit may generate the column select signal by driving an output node of the column select signal with a first drivability according to a column decoding signal, detect, based on a row decoding signal, information regarding a distance the column select signal will travel to perform a data read or write operation on a memory block among the plurality of memory blocks, and adjust the first drivability according to a detection result.

### BRIEF DESCRIPTION OF THE DRAWINGS

FIG. 1 is a diagram illustrating an example configuration of a semiconductor apparatus 10 according to an embodiment.

FIG. 2 is a diagram illustrating an example configuration of a memory block 110 of FIG. 1.

FIG. 3 is a diagram illustrating an example configuration of a column select signal generation circuit 300 of FIG. 1.

FIG. 4 is a diagram illustrating an example configuration of a semiconductor apparatus 11 according to an embodiment; and

FIG. 5 is a diagram illustrating an example configuration of a column select signal generation circuit 301 of FIG. 4.

### DETAILED DESCRIPTION

Hereinafter, a column select signal generation circuit and a semiconductor apparatus using the same according to various embodiments of the present disclosure will be described below with reference to the accompanying drawings.

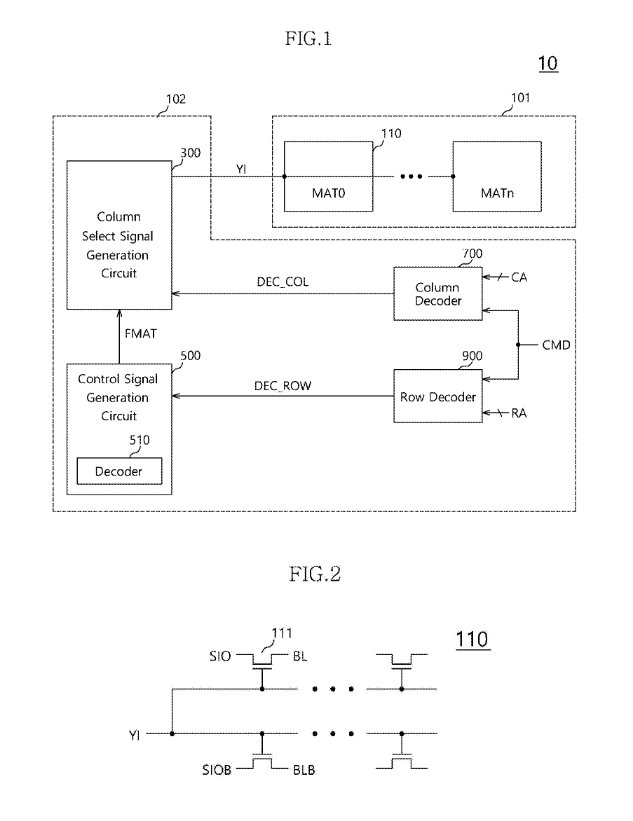

As illustrated in FIG. 1, a semiconductor apparatus 10 according to an embodiment may include a memory region 101 and a column select signal generation circuit 102.

The memory region 101 may include a plurality of memory blocks MAT0 to MATn.

Each of the memory blocks MAT0 to MATn may include a column path which may be enabled according to a column select signal YI.

The column select signal generation circuit 102 may generate the column select signal Y by driving an output node with a first drivability according to a column decoding signal DEC_COL. The column select signal generation circuit 102 may detect distance information of a memory block in which a data read or write operation is to be performed, among the plurality of memory blocks MAT0 to MATn, according to a row decoding signal DEC_ROW, and may adjust the first drivability according to a detection result to the distance information of the memory block.

The column select signal generation circuit 102 may include a column select signal generation circuit 300, a control signal generation circuit 500, a column decoder 700 and a row decoder 900.

The column select signal generation circuit 300 may generate the column select signal YI by driving the output node with the first drivability in response to the column decoding signal DEC_COL, and may adjust the first drivability according to a drivability control signal FMAT. For example, the column select signal generation circuit 300 may increase the first drivability.

The control signal generation circuit 500 may generate the drivability control signal FMAT according to the row decoding signal DEC_ROW.

The control signal generation circuit 500 may include a decoder 510.

The decoder 510 may generate the drivability control signal FMAT by decoding the row decoding signal DEC_ROW.

The column decoder 700 may generate the column decoding signal DEC_COL by decoding a column address CA and a command CMD.

The row decoder 900 may generate the row decoding signal DEC_ROW by decoding a row address RA and the command CMD.

As illustrated in FIG. 2, the plurality of memory blocks MAT0 to MATn may include a plurality of column switches 111, respectively.

The column switch 111 may couple column paths (e.g., a bit line BL/BLB) to a segment input/output line SIO/SIOB according to the column select signal YI during a data read/write process.

Furthermore, although not illustrated, the plurality of memory blocks may include memory cells, word lines and the like.

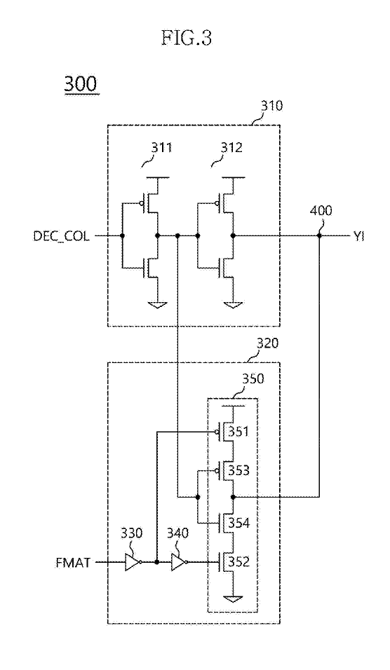

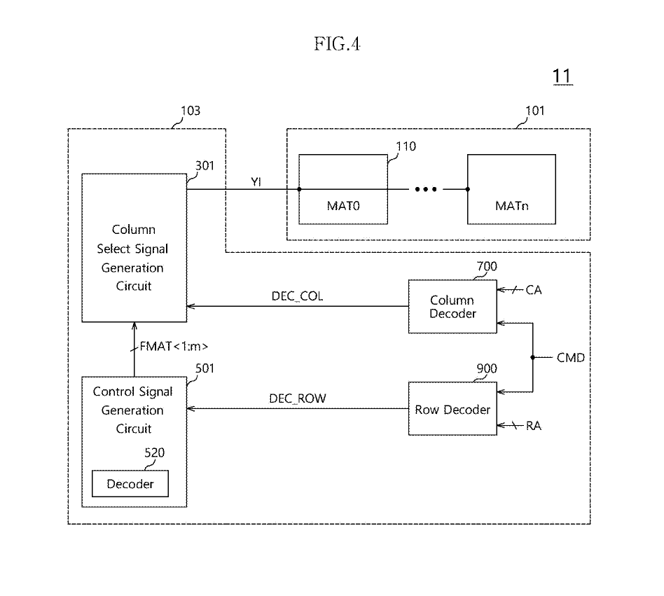

As illustrated in FIG. 3, the column select signal generation circuit 300 may include a driving circuit 310 and a drivability adjusting circuit 320.

The driving circuit 310 may generate the column select signal YI by driving an output node 400 with a current from one or more power supplies of the driving circuit 310, which operates in response to the column decoding signal DEC_COL.

The drivability adjusting circuit 320 may drive the output node 400 with a current from one or more power supplies of the drivability adjusting circuit 320, which operates according to an internal signal of the driving circuit 310 and the drivability control signal FMAT.

In an embodiment, the driving circuit 310 may include a first driver 311 and a second driver 312. The first driver 311 may receive the column decoding signal DEC_COL and generate an output signal by using a power supply coupled thereto, and the second driver 312 may drive the output node 400 with a current from a power supply of the second driver 312, which operates according to the output signal of the first driver 311.

In an embodiment, the drivability adjusting circuit 320 may include first and second inverters 330 and 340 and a third driver 350.

The first inverter 330 may invert the drivability control signal FMAT.

The second inverter 340 may invert the output signal of the first inverter 330.

The third driver 350 may drive the output node 400 with a current from one or more power supplies of the third driver 350, which operates according to the output signal of the first driver 311 and the drivability control signal FMAT.

In an embodiment, the third driver 350 may include first to fourth transistors 351 to 354 coupled between a power supply terminal and a ground terminal.

The first and second transistors 351 and 352 may open a current path from the power supply terminal to the ground terminal according to the output signals of the first and second inverters 330 and 340.

The third and fourth transistors 353 and 354 may open a current path between first and second transistors 351 and 352 according to the output signal of the first driver 311. In this way, the third driver 350 may drive the output node 400 with a current from the power supply terminal according to the output signal of the first driver 311 and the drivability control signal FMAT.

Hereafter, the operation of the semiconductor apparatus 10 according to an embodiment will be described.

The row address RA may include information regarding, among the plurality of memory blocks MAT0 to MATn, a memory block including a memory cell selected to be activated (e.g., information regarding a memory cell coupled to a word line (not illustrated) that is selected to be enabled), and the row decoding signal DEC_ROW obtained by decoding the row address RA may also include the information regarding the memory block including the memory cell selected to be activated.

In an embodiment, based on a signal transmission time difference of the column select signal YI or based on a signal strength of the column select signal YI, the physical distances to the memory blocks MAT0 to MATn may be divided into two ranges (for convenience, hereinafter referred to as “a first range Near” and “a second range Far).

The semiconductor apparatus 10 may detect, based on the row decoding signal DEC_ROW, whether the memory block including the memory cell selected to be activated belongs to the first range Near or the second range Far. For example, the plurality of memory blocks MAT0 to MATn may be divided into memory blocks MAT0 to MATk belonging to the first range Near and memory blocks MATk+1 to MATn belonging to the second range Far.

When the memory block including the memory cell selected to be activated is any one of the memory blocks MATk+1 to MATn belonging to the second range Far, the decoding logic of the decoder 510 of the control signal generation circuit 500 may activate the drivability control signal FMAT.

For example, when the memory cell selected to be activated is included in the memory block MAT0 that falls within the first range Near, the drivability control signal FMAT may be deactivated (e.g., the drivability control signal FMAT may be at a logic low level).

In this scenario, since the drivability control signal FMAT is at a logic low level, the current path of the third driver 350 of FIG. 3 may be blocked. Then, the driving circuit 310 may drive the output node 400 to generate the column select signal YI, but the drivability adjusting circuit 320 does not drive the output node 400.

On the other hand, when the memory cell selected to be activated is included in the memory block MATn that falls within the second range Far, the drivability control signal FMAT may be activated (e.g., the drivability control signal FMAT may be at a logic high level).

In this scenario, since the drivability control signal FMAT is at a high level, the current path of the third driver 350 of FIG. 3 may be opened, and the drivability adjusting circuit 320 may drive the output node 400.

As a result, since both the driving circuit 310 and the drivability adjusting circuit 320 drive the output node 400 when the memory block MAT0 of the first range Near is selected, the drivability of the column select signal generation circuit 300 may be improved.

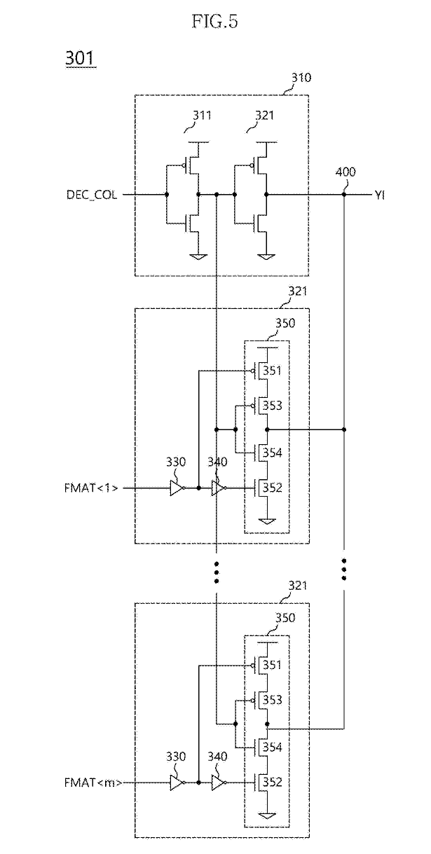

As illustrated in FIG. 4, a semiconductor apparatus 11 according to an embodiment may include a memory region 101 and a column select signal generation circuit 103.

The memory region 101 may include a plurality of memory blocks MAT0 to MATn.

The memory region 101 may be configured in the same manner as described with reference to FIGS. 1 and 2.

The column select signal generation circuit 103 may generate a column select signal Y by driving an output node with a first drivability according to a column decoding signal DEC_COL. The column select signal generation circuit 103 may detect, based on a row decoding signal DEC_ROW, whether a memory block selected to perform a data read or write operation, among the plurality of memory blocks MAT0 to MATn, belongs to the first range Near or the second range Far, and may adjust the first drivability according to the detection result.

The column select signal generation circuit 103 may include a column select signal generation circuit 301, a control signal generation circuit 501, a column decoder 700 and a row decoder 900.

The column select signal generation circuit 301 may generate the column select signal YI by driving the output node with the first drivability in response to the column decoding signal DEC_COL, and may adjust the first drivability according to a drivability control signal FMAT<1:m>. For example, the column select signal generation circuit 301 may increase the first drivability.

The control signal generation circuit 501 may generate the drivability control signal FMAT<1:m> according to the row decoding signal DEC_ROW.

The control signal generation circuit 501 may include a decoder 520.

The decoder 520 may generate the drivability control signal FMAT<1:m> by decoding the row decoding signal DEC_ROW.

The column decoder 700 may generate the column decoding signal DEC_COL by decoding a column address CA and a command CMD.

The row decoder 900 may generate the row decoding signal DEC_ROW by decoding a row address RA and the command CMD.

As illustrated in FIG. 5, the column select signal generation circuit 301 may include a driving circuit 310 and a plurality of drivability adjusting circuits 321.

The driving circuit 310 may be configured in the same manner as illustrated in FIG. 3.

The plurality of drivability adjusting circuits 321 may drive the output node 400 with a current from one or more power supplies of the plurality of drivability adjusting circuits 321, which operate according to an internal signal of the driving circuit 310 and the respective signal bits of the drivability control signal FMAT<1:m>.

Each of the drivability adjusting circuits 321 may be configured in the same manner as the drivability adjusting circuit 320 of FIG. 3.

Hereafter, the operation of the semiconductor apparatus 11 according to an embodiment will be described.

The row address RA may include information regarding a memory block including a memory cell selected to be activated (e.g., information regarding a memory cell coupled to a word line (not illustrated) that is selected to be enabled), among the plurality of memory blocks MAT0 to MATn, and the row decoding signal DEC_ROW obtained by decoding the row address RA may also include information regarding the memory block including the memory cell selected to be activated.

In an embodiment, based on the signal transmission time difference of the column select signal YI or based on a signal strength of the column select signal YI, the physical distances to the plurality of memory blocks MAT0 to MATn may be divided into a plurality of ranges, for example, (m+1) ranges.

The semiconductor apparatus 11 may detect, based on the row decoding signal DEC_ROW, which range of distance out of the (m+1) ranges of distances the memory block including the memory cell selected to be activated belongs to. In other words, the semiconductor apparatus 11 may detect, based on the row decoding signal DEC_ROW, which range of the distance the column select signal YI will travel to be provided to a memory block.

The decoding logic of the decoder 520 of the control signal generation circuit 501 may selectively activate the signal bits of the drivability control signal FMAT<1:m>. For example, according to the detection result indicating, among the (m+1) ranges, which range the memory block including the memory cell selected to be activated belongs to, the decoding logic of the decoder 520 of the control signal generation circuit 501 may deactivate all the signal bits of the drivability control signal FMAT<1:m>, or may activate all the signal bits of the drivability control signal FMAT<1:m>, or may activate parts of the signal bits of the drivability control signal FMAT<1:m>.

For example, under the supposition that m is set to 3 (m=3), the plurality of memory blocks MAT0 to MATn may be divided into four groups of ranges based on distance. In this case, the decoding logic of the decoder 520 of the control signal generation circuit 501 may be designed to deactivate all signal bits of the drivability control signal FMAT<1:3> when the memory block including the memory cell selected to be activated is in the first group, and may activate only one signal bit FMAT<1> of the drivability control signal FMAT<1:3> when the memory block including the memory cell selected to be activated is in the second group, and may activate two signal bits FMAT<1:2> of the drivability control signal FMAT<1:3> when the memory block including the memory cell selected to be activated is in the third group, and may activate all signals bits of the drivability control signal FMAT<1:3> when the memory block including the memory cell selected to be activated is in the fourth group.

For example, when the memory cell selected to be activated is included in the memory block MAT0 that falls within the first group, the drivability control signal FMAT<1:3> may have a value of “000.”

In this scenario, since the drivability control signal FMAT<1:3> is “000,” the current paths of the third drivers 350 of FIG. 5 may be blocked. Then, the driving circuit 310 may drive the output node 400 to generate the column select signal YI, but the plurality of drivability adjusting circuits 321 does not drive the output node 400.

When the memory cell selected to be activated is included in a memory block MATj that falls within the second group, the drivability control signal FMAT<1:3> may have a value of “100.”

In this scenario, since the drivability control signal FMAT<1:3> is “100,” the current path of the third driver 350 receiving the signal bit FMAT<1>, among the plurality of drivability adjusting circuits 321 of FIG. 5, may be opened to drive the output node 400.

When the memory cell selected to be activated is included in a memory block MATk that falls within the third group, the drivability control signal FMAT<1:3> may have a value of “110.”

In this scenario, since the drivability control signal FMAT<1:3> is “110,” the current paths of the third drivers 350 receiving the signal bits FMAT<1:2>, among the plurality of drivability adjusting circuits 321 of FIG. 5, may be opened to drive the output node 400.

As a result, since the number of drivability adjusting circuits 321 used to drive the output node 400 with the driving circuit 310 may vary according to the drivability control signal FMAT<1:m>, the drivability of the column select signal generation circuit 301 may be varied to various values according to the distance to the corresponding memory block.

While certain embodiments have been described above, it will be understood to those skilled in the art that the embodiments described are by way of example only. Accordingly, the semiconductor apparatus described herein should not be limited based on the described embodiments. Rather, the semiconductor apparatus described herein should only be limited in light of the claims that follow when taken in conjunction with the above description and accompanying drawings.

1. A semiconductor apparatus comprising:
a column select signal generation circuit configured to generate a column select signal by driving an output node of the column select signal generation circuit with a first drivability in response to a column decoding signal and adjust the first drivability according to a drivability control signal; and
a control signal generation circuit configured to generate the drivability control signal according to a row decoding signal,
wherein the column select signal generation circuit comprises:
a driving circuit configured to generate the column select signal by driving the output node according to the column decoding signal; and
a drivability adjusting circuit coupled to the driving circuit in parallel and configured to drive the output node according to an internal signal of the driving circuit when the drivability control signal is activated.

2. The semiconductor apparatus according to claim 1, wherein the control signal generation circuit is configured to acquire, based on the row decoding signal, information regarding a distance the column select signal will travel to be provided to a memory block, and generate the drivability control signal according to the distance information.

3. The semiconductor apparatus according to claim 1, wherein the control signal generation circuit comprises a decoder configured to generate the drivability control signal by decoding the row decoding signal.

4. (canceled)

5. The semiconductor apparatus according to claim 1, wherein the driving circuit comprises:
a first driver configured to receive the column decoding signal and generate an output signal; and
a second driver configured to drive the output node according to the output signal of the first driver.

6. The semiconductor apparatus according to claim 5, wherein the drivability adjusting circuit comprises a third driver configured to drive the output node according to the output signal of the first driver and the drivability control signal.

7. The semiconductor apparatus according to claim 1, further comprising:
a column decoder configured to generate the column decoding signal according to a column address and a command; and
a row decoder configured to generate the row decoding signal according to a row address and the command.

8. The semiconductor apparatus according to claim 1, wherein the control signal generation circuit is configured to detect, according to the row decoding signal, which range of a distance the column select signal will travel to be provided to a memory block, among a plurality of ranges of distances, and generate the drivability control signal according to a detection result.

9. The semiconductor apparatus according to claim 8, wherein the column select signal generation circuit comprises:
a driving circuit configured to generate the column select signal by driving the output node according to the column decoding signal; and
a plurality of drivability adjusting circuits configured to drive the output node according to an internal signal of the driving circuit and the respective signal bits of the drivability control signal.

10. The semiconductor apparatus according to claim 9, wherein the driving circuit comprises:
a first driver configured to receive the column decoding signal and generate an output signal; and
a second driver configured to drive the output node according to the output signal of the first driver

11. The semiconductor apparatus according to claim 10, wherein the plurality of drivability adjusting circuits comprise third drivers configured to drive the output node according to the output signal of the first driver and the respective signal bits of the drivability control signal.

12. A semiconductor apparatus comprising:
a memory region comprising a plurality of memory blocks having a column path which is enabled according to a column select signal; and
a column select signal generation circuit configured to generate the column select signal by driving an output node of the column select signal generation circuit with a first drivability according to a column decoding signal, detect, based on a row decoding signal, information regarding a distance the column select signal will travel to perform a data read or write operation on a memory block among the plurality of memory blocks, and adjust the first drivability according to a detection result,
wherein the column select signal generation circuit comprises:
a driving circuit configured to generate the column select signal by driving the output node according to the column decoding signal; and
a drivability adjusting circuit coupled to the driving circuit in parallel and configured to drive the output node according to an internal signal of the driving circuit when a drivability control signal is activated.

13. The semiconductor apparatus according to claim 12, wherein the column select signal generation circuit further comprises:
a control signal generation circuit configured to generate the drivability control signal according to a row decoding signal.

14. (canceled)

15. The semiconductor apparatus according to claim 12, wherein the driving circuit comprises:
a first driver configured to receive the column decoding signal and generate an output signal; and
a second driver configured to drive the output node according to the output signal of the first driver.

16. The semiconductor apparatus according to claim 15, wherein the drivability adjusting circuit comprises a third driver configured to drive the output node according to the output signal of the first driver and the drivability control signal.

17. The semiconductor apparatus according to claim 13, further comprising:
a column decoder configured to generate the column decoding signal according to a column address and a command; and
a row decoder configured to generate the row decoding signal according to a row address and the command.

18. The semiconductor apparatus according to claim 13, wherein the control signal generation circuit is configured to detect, according to the row decoding signal, which range of a distance the column select signal will travel to be provided to the memory block, among a plurality of ranges of distances, and generate the drivability control signal according to the detection result.

19. The semiconductor apparatus according to claim 18, wherein the column select signal generation circuit comprises:
a driving circuit configured to generate the column select signal by driving the output node according to the column decoding signal; and
a plurality of drivability adjusting circuits configured to drive the output node according to an internal signal of the driving circuit and the respective signal bits of the drivability control signal.
